(19) United States
(12) Patent Application Publication
(10) Pub. No.: US 2018/0277454 A1
(43) Pub. Date: Sep. 27, 2018

(54) SUBSTRATE TREATMENT APPARATUS AND SUBSTRATE TREATMENT METHOD

(71) Applicant: SCREEN Holdings Co., Ltd., Kyoto (JP)

(72) Inventors: Koji KURASAKI, Kyoto-shi (JP); Kenji EDAMITSU, Kyoto-shi (JP); Masaharu SATO, Kyoto-shi (JP); Kei TAKECHI, Kyoto-shi (JP); Takeshi MATSUMURA, Kyoto-shi (JP); Hiroaki UCHIDA, Kyoto-shi (JP); Shigeru YAMAMOTO, Kyoto-shi (JP); Tomohiro TAKAHASHI, Kyoto-shi (JP); Hironobu IWATANI, Kyoto-shi (JP); Shinji SUGIOKA, Kyoto-shi (JP)

(21) Appl. No.: 15/890,429

(22) Filed: Feb. 7, 2018

(30) Foreign Application Priority Data
Mar. 27, 2017 (JP) 2017-060474

(51) Int. Cl. H01L 21/66; C03C 15/00; H01L 21/67; H01L 21/3213

(52) U.S. Cl. CPC H01L 22/26; C03C 15/00; H01L 21/32134; H01L 21/67253; H01L 21/67086

(57) ABSTRACT

A substrate treatment method according to the present invention is a substrate treatment method of treating at least one substrate in a treatment tank with treatment liquid. The substrate treatment method includes the following processes of: acquiring in advance treatment information of the substrate to be treated in the treatment tank; specifying a predicted concentration change pattern corresponding to the acquired treatment information of the substrate by referencing correspondence information describing a plurality of situations possible for the treatment information and a plurality of concentration change patterns of the treatment liquid prepared in advance to respectively correspond to the plurality of situations of the treatment information; and carrying out concentration control of the treatment liquid based on the predicted concentration change pattern while the substrate is treated in the treatment tank.

### BACKGROUND OF THE INVENTION

### Field of the Invention

The present invention relates to a substrate treatment apparatus and a substrate treatment method for treating substrates such as semiconductor substrates, liquid-crystal-display glass substrates, or photomask glass substrates with treatment liquid.

### Description of the Background Art

Conventionally, there is known a substrate treatment apparatus of an immersion type which treats substrates by immersing the substrates in treatment liquid such as pure water or chemical solution in a manufacturing process of substrates such as semiconductor substrates, liquid-crystal-display glass substrates, or photomask glass substrates.

The substrate treatment apparatus of the immersion type is provided with a treatment tank for storing the treatment liquid used in treatment of the substrates. Cleaning treatment, etc. of the substrates are carried out in the treatment tank.

In the above described treatment, in order to uniformize the treatment for the substrates, the concentration of the treatment liquid in the treatment tank is controlled. For example, as exemplified in Japanese Patent Application Laid-Open No. 2009-260257, at the point of time when the treatment for a certain number of substrates is finished, the concentration of the treatment liquid is adjusted, for example, by replacing the treatment liquid. Then, the treatment for the next substrates is carried out.

However, if the concentration change of the treatment liquid caused along the treatment of the substrates is large, in the above described method of adjusting the concentration of the treatment liquid at the point of time when the substrate treatment is finished, it has been difficult in some cases to uniformize the treatment for the substrates since the concentration of the treatment liquid during the treatment is not constant.

### SUMMARY

The present invention is directed to a substrate treatment method of treating substrates with treatment liquid.

According to one aspect of the present invention, an object holding method of treating at least one substrate in a treatment tank with treatment liquid includes the following processes of: acquiring in advance treatment information of the substrate to be treated in the treatment tank; specifying a predicted concentration change pattern corresponding to the acquired treatment information of the substrate by referencing correspondence information describing a plurality of situations possible for the treatment information and a plurality of concentration change patterns of the treatment liquid prepared in advance to respectively correspond to the plurality of situations of the treatment information; and carrying out concentration control of the treatment liquid based on the predicted concentration change pattern while the substrate is treated in the treatment tank.

The information about the plurality of concentration change patterns prepared in advance to respectively correspond to the plurality of situations possible for the treatment information of the substrate is prepared, and the concentration of the treatment liquid can be controlled based on the predicted concentration change pattern corresponding to the treatment information of the point of time while the substrate is treated. Therefore, even if the concentration change of the treatment liquid caused along the treatment of the substrate is large, the concentration of the treatment liquid can be appropriately controlled while the substrate is treated in accordance with the situation shown by the treatment information of the substrate.

Preferably, the process of replenishing replenishment liquid to the treatment tank while the substrate is treated in the treatment tank is further included. Concentration control of the treatment liquid is carried out by controlling the amount of the replenishment liquid replenished based on the predicted concentration change pattern.

By replenishing the replenishment liquid while the substrate is treated, the concentration of the treatment liquid can be controlled while suppressing concentration changes of the treatment liquid during the treatment of the substrate.

Preferably, the substrate is a substrate having a stacked structure.

Even if the concentration of the treatment liquid is largely changed along with the treatment of the stacked substrate which has a large amount of etching, the concentration of the treatment liquid can be maintained while the substrate is treated.

Preferably, the replenishment liquid replenished to the treatment tank has undergone temperature adjustment based on a temperature of the treatment liquid.

As a result of adjusting the temperature of the replenishment liquid to a temperature close to the temperature of the treatment liquid in the treatment tank, the temperature of the treatment liquid in the treatment tank is not easily changed even in a case in which the replenishment liquid is replenished. Therefore, even in a case in which the replenishment liquid is replenished, the treatment of the substrate can be continued in the state in which the temperature of the treatment liquid is appropriately maintained.

The present invention is also directed to a substrate treatment apparatus which treats substrates with treatment liquid.

According to one aspect of the present invention, a substrate treatment apparatus includes: a treatment tank that stores treatment liquid and immerses at least one substrate in the stored treatment liquid to carry out substrate treatment of the substrate; a backup tank that is provided separately from the treatment tank, the backup tank replenishing replenishment liquid prepared to a predetermined concentration toward the treatment tank; liquid sending means that sends the replenishment liquid from the backup tank toward the treatment tank; an acquisition part that acquires in advance treatment information about the substrate to be immersed in the treatment tank; a storage part that stores correspondence information describing a plurality of situations possible for the treatment information and describing a plurality of concentration change patterns prepared in advance to respectively correspond to the plurality of situations of the treatment information; a specifying part that specifies a predicted concentration change pattern corresponding to the treatment information of the substrate acquired by the acquisition part by referencing the correspondence information; and control means that executes concentration prediction control of predicting a future concentration of the treatment liquid based on the specified predicted concentration change pattern, replenishment liquid concentration specifying control of specifying the concentration of replenishment liquid capable of changing the future concentration, preparation control of preparing the replenishment liquid in advance in the backup tank before replenishing the replenishment liquid from the backup tank toward the treatment tank, and liquid sending control of controlling the liquid sending means so as to send the prepared replenishment liquid from the backup tank toward the treatment tank during the substrate treatment.

The control part can predict the future concentration of the treatment liquid, in which the substrate is immersed, by the specifying part based on the specified predicted concentration change pattern. By virtue of this, the control part can prepare the replenishment liquid, which has the concentration capable of changing the future concentration of the treatment liquid, in the backup tank before the replenishment liquid is actually replenished to the treatment tank. By virtue of this, the concentration of the treatment liquid can be quickly changed during the substrate treatment.

According to one aspect of the present invention, in a substrate treatment method of a substrate treatment apparatus having: a treatment tank that stores treatment liquid and immerses at least one substrate in the stored treatment liquid to carry out substrate treatment of the substrate; a backup tank that is separately provided from the treatment tank, the backup tank replenishing replenishment liquid prepared to a predetermined concentration toward the treatment tank; liquid sending means that sends the replenishment liquid from the backup tank toward the treatment tank; and a storage part that in advance stores correspondence information describing a plurality of situations possible for the treatment information and describing a plurality of concentration change patterns of the treatment liquid prepared in advance to respectively correspond to the plurality of situations of the treatment information, the substrate treatment method includes the following processes of: acquiring in advance treatment information about the substrate to be immersed in the treatment tank; specifying a predicted concentration change pattern corresponding to the acquired treatment information of the substrate by referencing the correspondence information; predicting a future concentration of the treatment liquid based on the specified predicted concentration change pattern; specifying the concentration of the replenishment liquid capable of changing the future concentration; preparing the replenishment liquid in the backup tank in advance before replenishing the replenishment liquid from the backup tank toward the treatment tank; and sending the prepared replenishment liquid from the backup tank toward the treatment tank during the substrate treatment.

The future concentration of the treatment liquid, in which the substrate is immersed, can be predicted based on the specified predicted concentration change pattern. By virtue of this, the replenishment liquid, which has the concentration capable of changing the future concentration of the treatment liquid, can be prepared in the backup tank before the replenishment liquid is actually replenished to the treatment tank. By virtue of this, the concentration of the treatment liquid can be quickly changed during the substrate treatment. Therefore, it is an object of the present invention to provide techniques with which the concentration of the treatment liquid can be controlled while the substrate is treated even in a case in which the concentration change of the treatment liquid caused along with the treatment of the substrate is large.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram schematically exemplifying the constitutions of a substrate treatment apparatus according to a preferred embodiment;

FIG. 2 is a flow chart exemplifying the operation of the substrate treatment apparatus according to the preferred embodiment;

FIG. 3 is an illustration showing an example of a correspondence table which describes a plurality of situations possible for treatment information of substrates and a plurality of concentration change patterns of change components in a manner that the situations and the patterns are mutually associated;

FIG. 4 is a schematic view showing an example of a concentration change pattern of a change component;

FIG. 5 is a view schematically exemplifying the constitutions of the substrate treatment apparatus according to a preferred embodiment of a case with a concentration meter which measures the concentration of a change component in treatment liquid;

FIG. 6 is a view showing an example of a stacked substrate;

FIG. 7 is a view showing an example of a stacked substrate;

FIG. 8 shows an example of a correspondence table which is different from that described by using FIG. 3;

FIG. 9 is an illustration showing a standard pattern, a concentration change pattern (pattern 2), and a concentration change pattern (pattern 1);

FIG. 10 is a graph showing time lapse changes of the silicon concentration of the treatment liquid;

FIG. 11 is a flow chart for describing a control flow;

FIG. 12 shows an example of a correspondence table which describes a plurality of treatment information and concentration change patterns in a manner that they are mutually associated; and

FIG. 13 is an illustration showing a standard pattern, a concentration change pattern (pattern 10), and a concentration change pattern (pattern 11).

### DESCRIPTION OF THE PREFERRED EMBODIMENT

Hereinafter, a preferred embodiment will be described with reference to attached drawings.

Note that drawings are schematically shown, constitutions thereof are omitted or simplified appropriately in order to facilitate explanations. The interrelations of the sizes and positions of the constitutions, etc. shown in different drawings are not always precisely described, but are appropriately changeable.

In the description shown below, similar constituent elements are shown with the same reference signs, and the names and functions thereof are also considered to be similar. Therefore, detailed descriptions about them may be omitted in order to avoid redundancy.

In the descriptions described below, even if the terms such as “upper”, “lower”, “left”, “right”, “side”, “bottom”, “front”, or “rear” which mean particular positions and directions are used, these terms are used for the sake of convenience in order to facilitate understanding the contents of the preferred embodiment, and these are not related to the directions of actually implemented cases.

<Preferred Embodiment>

Hereinafter, a substrate treatment apparatus and a substrate treatment method according to a present preferred embodiment will be described.

<About Constitutions of Substrate Treatment Apparatus>

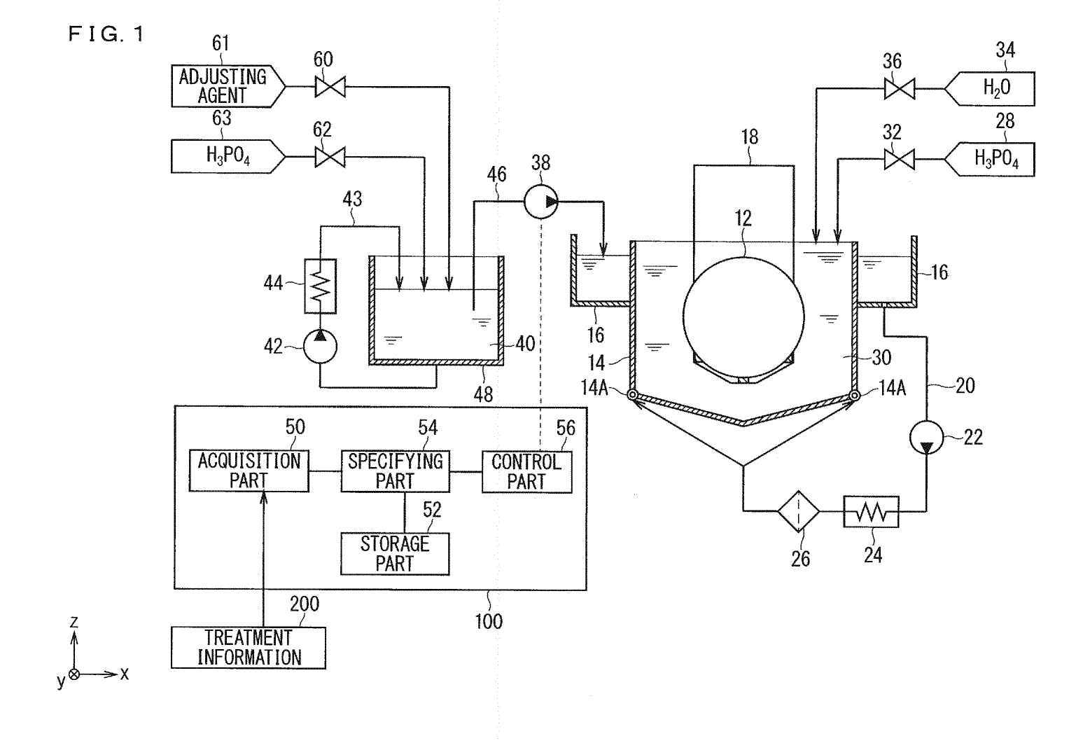

FIG. 1 is a diagram schematically exemplifying the constitutions of the substrate treatment apparatus according to the present preferred embodiment. In FIG. 1, a substrate 12 is disposed in parallel to the surface of the paper. Note that a plurality of similarly disposed substrates 12 may be juxtaposed in a y-axis direction of FIG. 1.

As exemplified in FIG. 1, a substrate treatment apparatus is provided with: a treatment tank 14, an outer tank 16, a circulation path 20, a replenishment path 46, and a control device 100.

The substrates 12 are substrates such as semiconductor substrates, liquid-crystal-display glass substrates, or photomask glass substrates. The substrate 12 is maintained in an upright orientation by a lifter 18. Note that, in the case exemplified in FIG. 1, the plurality of substrates 12 are retained by the lifter 18 and treated. However, the number of the treated substrate 12 may be one. The lifter 18 is connected to a lifter drive part (not illustrated herein) having a servomotor, a timing belt, or the like. When the lifter drive part is operated, the lifter 18 moves up/down, in other words, moves in a z-axis direction of FIG. 1. As a result, the substrates 12 can be moved between a treatment position in the treatment tank 14 and a pull-up position above the treatment tank 14. When the substrates 12 are to be treated in the treatment tank 14, the substrates 12 are positioned at the treatment position in the treatment tank 14 by lowering the lifter 18. In the time between the treatment of certain substrates and the treatment of next substrates, the substrates 12 are positioned at the pull-up position above the treatment tank 14 by elevating the lifter 18.

The treatment tank 14 is a container which stores treatment liquid 30 for treating the substrates 12. Cleaning treatment, etc. of the substrates 12 are carried out by immersing the substrates 12 in the treatment liquid 30 stored in the treatment tank 14. The treatment liquid 30 is, for example, pure water or phosphoric acid, which is an etching liquid. The pure water is supplied from a pure-water supply source 34 by opening/closing a valve 36. The phosphoric acid is supplied from a phosphoric-acid supply source 28 by opening/closing a valve 32.

Treatment-liquid discharge parts 14A are provided at a bottom part of the treatment tank 14. The treatment-liquid discharge parts 14A discharge the treatment liquid 30, which flows in the circulation path 20, into the treatment tank 14.

The outer tank 16 is provided to surround the treatment tank 14. As exemplified in FIG. 1, the outer tank 16 is attached to an upper lateral surface of the treatment tank 14 so as to surround an opening of the treatment tank 14.

The treatment liquid 30 supplied to the treatment tank 14 flows out, in other words, overflows from the upper part of the treatment tank 14. Then, the treatment liquid 30 flows into the outer tank 16 surrounding the treatment tank 14.

The circulation path 20 is a path which returns the treatment liquid 30, which has overflowed from the upper part of the treatment tank 14 and further flowed into the outer tank 16, again to the treatment-liquid discharge parts 14A at lower parts of the treatment tank 14. The circulation path 20 is a path which has one end connected to, for example, a bottom part of the outer tank 16, has another end connected to the treatment-liquid discharge parts 14A of the treatment tank 14, and is formed by piping for flowing the treatment liquid 30.

As exemplified in FIG. 1, a pump 22 for flowing the treatment liquid 30, a heater 24 for heating the treatment liquid 30 in the circulation path 20, and a filter 26 for removing the particles in the treatment liquid 30 flowing in the circulation path 20 are disposed in this order on the circulation path 20. Note that the disposed positions of the pump 22, the heater 24, and the filter 26 on the circulation path 20 are not limited to those of the case exemplified in FIG. 1.

The replenishment path 46 is a path which replenishes replenishment liquid 40 from a backup tank 48 to the outer tank 16. The replenishment path 46 is a path formed by piping which flows the replenishment liquid 40. As exemplified in FIG. 1, a pump 38 for sending the replenishment liquid 40 to the treatment tank 14 through the outer tank 16 is disposed on the replenishment path 46.

The backup tank 48 is a container which stores the replenishment liquid 40. In the backup tank 48, a plurality of treatment liquids are circulated and mixed to prepare the replenishment liquid 40 having a predetermined concentration. Examples of the plurality of treatment liquids mixed in the backup tank 48 include phosphoric acid, which is an etching liquid, and a concentration adjusting agent. In this case, the phosphoric acid is supplied from a phosphoric-acid supply source 63 to the backup tank 48 by opening/closing of a valve 62. The concentration adjusting agent is supplied from an adjusting-agent supply source 61 to the backup tank 48 by opening/closing of a valve 60. In this case, the replenishment liquid 40 having a predetermined phosphoric acid concentration and a predetermined silicon concentration is prepared in the backup tank 48.

Note that, as the concentration adjusting agent, a chemical solution corresponding to the components (hereinafter, referred to as change components) in the treatment liquid 30 which undergoes change of concentration caused by treatment of the substrates 12 is selected. For example, if the silicon concentration in the treatment liquid 30 is changed by etching treatment of the substrates 12, a silicon-concentration adjusting agent is selected.

A circulation path 43 is connected to the backup tank 48. The circulation path 43 is a path which causes the replenishment liquid 40 to flow in from, for example, a bottom part of the backup tank 48 and causes the replenishment liquid 40 to return from, for example, an upper part of the backup tank 48 again. The circulation path 43 has one end connected to, for example, the bottom part of the backup tank 48, has another end disposed at, for example, the upper part of the backup tank 48, and is a path formed by piping for flowing the replenishment liquid 40.

As exemplified in FIG. 1, a pump 42 for flowing the replenishment liquid 40 and a heater 44 for heating the replenishment liquid 40 in the circulation path 43 are disposed in this order on the circulation path 43. Note that the disposed positions of the pump 42 and the heater 44 on the circulation path 43 are not limited to those of the case exemplified in FIG. 1. By circulating the replenishment liquid 40 by the circulation path 43, the replenishment liquid 40 stored in the backup tank 48 is circulated and is subjected to temperature adjustment by the heater 44 to a temperature suitable for the substrate treatment in the treatment tank 14, and at the same time, the phosphoric acid and the concentration adjusting agent, which are the plurality of treatment liquids, are mixed.

The control device 100 is provided with an acquisition part 50, a specifying part 54, a storage part 52, and a control part 56.

The acquisition part 50 is an input device(s) such as a mouse, a keyboard, a touchscreen, or various switches from which information can be input. The acquisition part 50 acquires treatment information 200 of the substrates 12, which are to be treated in the treatment tank 14, before the treatment of the substrates 12.

The storage part 52 stores a correspondence table which describes the treatment information of the substrates 12 and a plurality of time-lapse concentration change patterns of the treatment liquid 30 stored in the treatment tank 14 corresponding to a plurality of situations possible for the treatment information in a manner that the treatment information and the patterns are mutually associated. Examples of the storage part 52 include volatile or non-volatile semiconductor memories such as a hard disk (HDD), a random access memory (RAM), a read-only memory (ROM), and a flash memory and memories (storage media) including a magnetic disk, a flexible disk, an optical disk, a compact disk, a mini disk, a DVD, etc.

The specifying part 54 references the correspondence table stored in the storage part 52, thereby specifying a single time-lapse concentration change pattern of the treatment liquid 30 corresponding to the treatment information of the substrates 12 acquired by the acquisition part 50 among the plurality of concentration change patterns as a predicted concentration change pattern.

The control part 56 is electrically connected to the lifter drive part, the valve 32, the valve 36, the valve 60, the valve 62, the pump 22, the pump 38, the pump 42, the heater 24, the heater 44, etc. so as to control operations thereof. Specifically, the control part 56 controls driving of the pump 38 based on the predicted concentration change pattern of the treatment liquid 30 which is specified by the specifying part 54 and corresponding to the treatment information of the substrates 12.

The specifying part 54 and the control part 56 are, for example, a central processing unit (CPU), a micro processor, or a micro computer which executes a program(s) stored in the storage part 52, an external CD-ROM, an external DVD-ROM, or an external flash memory. Note that each of the function of the specifying part 54 and the function of the control part 56 may be realized, for example, by cooperation of a plurality of processing circuits.

In FIG. 1, all of the acquisition part 50, the storage part 52, the specifying part 54, and the control part 56 are provided in the control device 100. However, the function parts thereof may be provided in a manner that they are dispersed among a plurality of devices.

<About Operation of Substrate Treatment Apparatus>

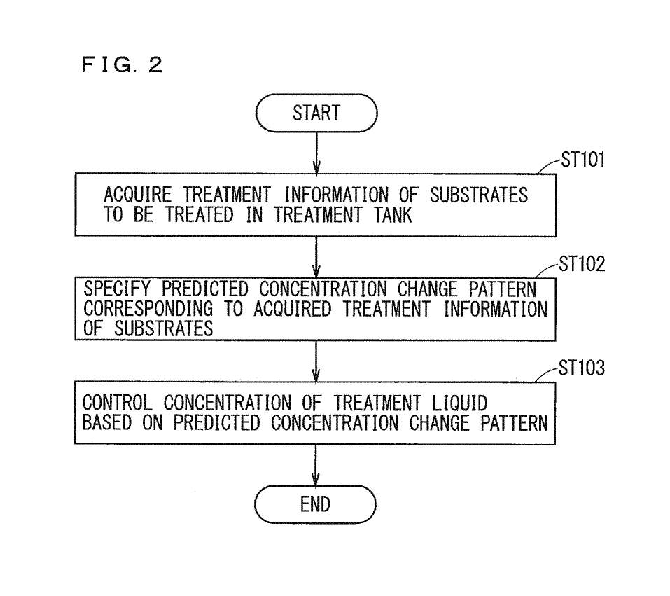

Next, operation of the substrate treatment apparatus according to the present preferred embodiment will be described with reference to FIG. 2 to FIG. 4. Herein, FIG. 2 is a flow chart exemplifying the operation of the substrate treatment apparatus according to the present preferred embodiment.

First, the operation of the substrate treatment apparatus in normal substrate treatment will be described. As exemplified in FIG. 1, when the lifter 18 is lowered, the substrates 12 are positioned at the treatment position in the treatment tank 14. Then, cleaning treatment, etc. of the substrates 12 are carried out by immersing the substrates 12 in the treatment liquid 30 stored in the treatment tank 14. On the other hand, as a result of supplying of pure water and phosphoric acid to the treatment tank 14, the treatment liquid 30 overflows from the treatment tank 14. Then, the treatment liquid 30 overflowed from the treatment tank 14 flows into the outer tank 16.

The treatment liquid 30 overflowed to the outer tank 16 flows into the circulation path 20. The treatment liquid 30 which is caused to flow to the circulation path 20 by the pump 22 is subjected to temperature adjustment by the heater 24 and removal of the particles in the treatment liquid 30 by the filter 26. Herein, the temperature control of the heater 24 is carried out by the control part 56.

The temperature of the treatment liquid 30 which flows in the circulation path 20 becomes close to the temperature of the treatment liquid 30 in the treatment tank 14 as a result of carrying out the temperature adjustment by the heater 24. Moreover, since the particles in the treatment liquid 30 which flows in the circulation path 20 are removed by the filter 26, the particles can be prevented from being mixed into the treatment tank 14. Then, the treatment liquid 30 which flows in the circulation path 20 is discharged into the treatment tank 14 from the treatment-liquid discharge part 14A.

Next, the operation of the substrate treatment apparatus related to concentration control of the treatment liquid 30 which is carried out in parallel with the above described substrate treatment, in other words, carried out while the substrates 12 are treated in the treatment tank 14 will be described.

First, the acquisition part 50 acquires the treatment information of the substrates 12 which are to be treated in the treatment tank 14 thereafter (step ST101 exemplified in FIG. 2). Herein, the treatment information of the substrates 12 is, for example, information about the number of the substrates 12 which are to be immersed at the same time in the treatment tank 14, the type and liquid temperature of the treatment liquid 30, the time for treating the substrates 12 in the treatment tank 14, the speed (for example, etching rate) for treating the substrates 12 in the treatment tank 14, or the liquid contact area of the pattern formed at the substrates 12 treated in the treatment tank 14.

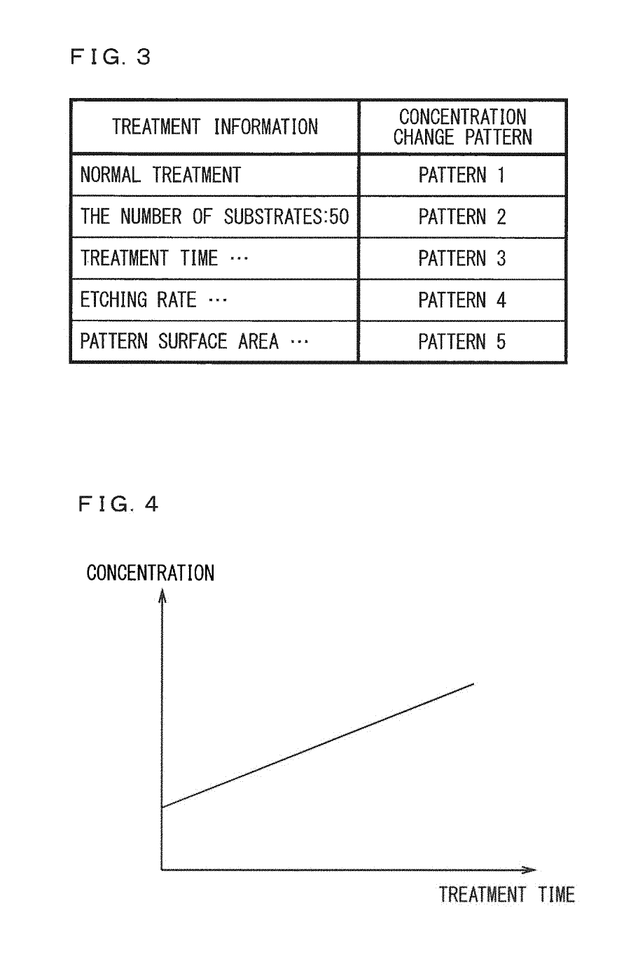

Then, the specifying part 54 specifies the predicted concentration change pattern of the treatment liquid 30 corresponding to the treatment information of the substrates 12 acquired by the acquisition part 50 while referencing the correspondence table stored in the storage part 52 (step ST102 exemplified in FIG. 2). Herein, the correspondence table is a table as exemplified in FIG. 3 which is prepared to correspond to each of a plurality of situations of the treatment information of the substrates 12 and is described in association with the plurality of concentration change patterns of the treatment liquid 30. More precisely, the correspondence table is a table which describes the plurality of situations possible for the treatment information of the substrates 12 and the time-lapse concentration change patterns of substance components (change components such as silicon) in the treatment liquid 30, which undergoes concentration change caused by the treatment of the substrates 12, in a manner that the situations and the substance components are mutually associated. Note that FIG. 3 is an illustration showing an example of such a correspondence table.

In FIG. 3, the concentration change pattern of the change component in the treatment liquid 30 corresponding to “normal treatment” of the substrates 12 is described as “pattern 1”, and in other rows, only the items in which values different from those of “normal treatment” are used are described as the items of “treatment information”, and the pattern names of the concentration change patterns of the change components corresponding thereto are described as the items of “concentration change patterns”. Note that the change component in the treatment liquid 30 is not limited to a single species of substance, but may be a combination of a plurality of species of substances. For example, the change component may be a combination or the like of a silicon concentration and a phosphoric acid concentration.

The concentration change pattern of the change component represents the relation between the treatment time of the substrates 12 and the concentration of the change component in the treatment liquid 30 as exemplified in FIG. 4. The concentration change pattern of the change component is a reference pattern obtained by carrying out treatment of the substrates 12 beforehand under the conditions to which the treatment information of the substrates 12 is reflected and measuring the concentration (for example, a silicon concentration) of the change component in the treatment liquid 30 under the conditions, in other words, the concentration change pattern is a pattern which predicts the concentration changes in this situation. Herein, FIG. 4 is a schematic view showing an example of the concentration change pattern of the change component, the vertical axis in the view shows the concentration of the change component, and the horizontal axis shows the treatment time of the substrates. Note that the change of the concentration of the change component is not limited to the increase at a certain rate as exemplified in FIG. 4, but, for example, a case in which the amount of increase of the concentration of the change component is varied and a case in which the concentration of the change component decreases are also possible. These patterns are not limited to linear patterns, but may be curve patterns. The patterns may be expressed as columns of numerical values on a table as exemplified in the present preferred embodiment or may be expressed as a function which uses the treatment information as a variable number. Therefore, the correspondence information is not required to be in the form of table.

Then, the control part 56 controls the concentration of the change component in the treatment liquid 30 based on the concentration change pattern of the change component specified by the specifying part 54 (predicted concentration change pattern) (step ST103 exemplified in FIG. 2). Specifically, the control part 56 controls driving of the pump 38, which is for replenishing the replenishment liquid 40, based on the predicted concentration change pattern.

For example, if the predicted concentration change pattern shows that the concentration of the change component increases or decreases after a certain period of time after the treatment is started, the control part 56 drives the pump 38 in accordance with the time so that the control part 56 replenishes the replenishment liquid 40 having the concentration capable of changing the future concentration of the change component predicted based on the predicted concentration change pattern.

This control is carried out while the substrates 12 are treated in the treatment tank 14. More specifically, at the timing before the concentration of the change component in the treatment liquid 30 used for treating the substrates 12 changes over a predetermined permissible range, the replenishment liquid 40 is replenished so as to change the future concentration of the change component predicted based on the predicted concentration change pattern.

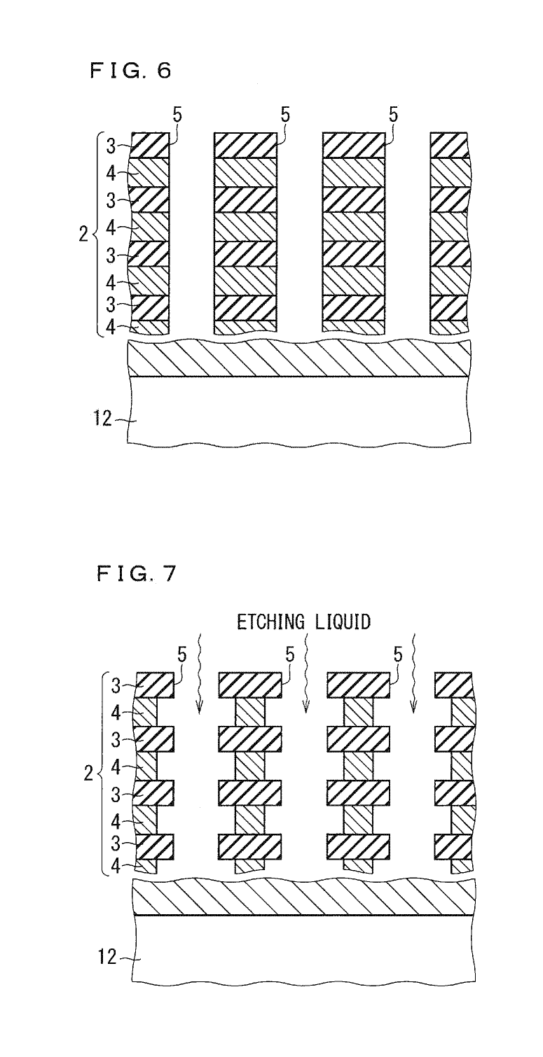

Such control is particularly effective in a case during treatment of the substrates 12 in which it is difficult to maintain the concentration of the treatment liquid 30 at a constant level, in other words, in a case in which the concentration change caused along with the treatment of the substrates 12 is large. As the case in which the concentration change caused along with the treatment of the substrates 12, a case in which a stacked substrate having a 3-dimensional surface pattern is to be formed by etching treatment, in other words, for example, treatment of a substrate having a large amount of etching is expected. FIG. 6 shows an example of such a stacked substrate. Plural layers of oxide films 3 and plural layers of polysilicon film 4 are stacked on an upper surface of the substrate 12, and holes 5 penetrating through these plural layers in the stacked direction thereof are formed. When this substrate 12 is immersed in etching liquid, the etching liquid enters the holes 5, the polysilicon layers 4 are selectively etched from inner peripheral surfaces (lateral walls) of the holes 5 as shown in FIG. 7, and the polysilicon layers 4 retract from the inner peripheral surfaces of the holes 5. As a result, the structure in which the oxide films 3 are projecting from the inner peripheral surfaces (lateral walls) of the holes 5 to the inner side is obtained. As the number of the films stacked on the substrate 12 is increased and as the holes 5 are deepened, the liquid contact area of the inner peripheral surfaces of the holes 5 with respect to the etching liquid increases, and therefore, the amount of etching per unit time increases. The amount of silicon which dissolves from the substrate to the etching liquid is correlated to the amount of etching. Therefore, if a substrate having a large number of stacking is to be treated (etched), the concentration change of the change component (silicon) in the treatment liquid 30 caused along with the treatment is larger than the case in which a substrate having a small number of stacking is treated.

On the other hand, the replenishment liquid 40 used in the concentration control is stored in the backup tank 48, and the replenishment liquid 40 is circulated by the circulation path 43 connected to the backup tank 48. Since the heater 44 for heating the replenishment liquid 40 is disposed on the circulation path 43, the replenishment liquid 40 in the backup tank 48 is maintained in a state in which the liquid is adjusted to a desired temperature. The temperature of the replenishment liquid 40 in the backup tank 48 can be adjusted by controlling the output of the heater 44 by the control part 56.

As a result of adjusting the temperature of the replenishment liquid 40 in the backup tank 48 to a temperature close to the temperature of the treatment liquid 30 in the treatment tank 14, the temperature of the treatment liquid 30 in the treatment tank 14 is not easily changed even in a case in which the replenishment liquid 40 is replenished. In other words, even in the case in which the replenishment liquid 40 is replenished while the substrates 12 are treated, the treatment of the substrates 12 can be continued in a state in which the temperature of the treatment liquid 30 is appropriately maintained.

The phosphoric acid from the phosphoric-acid supply source 63 and the concentration adjusting agent from the adjusting-agent supply source 61 are supplied to the backup tank 48. The control part 56 can adjust, for example, the amount of the replenishment liquid 40 stored in the backup tank 48 or the silicon concentration in the replenishment liquid 40 by controlling opening/closing of the valve 60 and opening/closing of the valve 62. Therefore, the control part 56 can store the replenishment liquid 40, which has the amount and concentration capable of changing the concentration of the change component in the treatment liquid 30, in the backup tank 48 in accordance with the predicted concentration change pattern specified by the specifying part 54.

Herein, in the above described concentration control of the treatment liquid 30, a concentration meter which measures the concentration of the change component in the treatment liquid 30 can be further provided. In that case, the control part 56 can also carry out feedback control using a measured value according to the concentration meter.

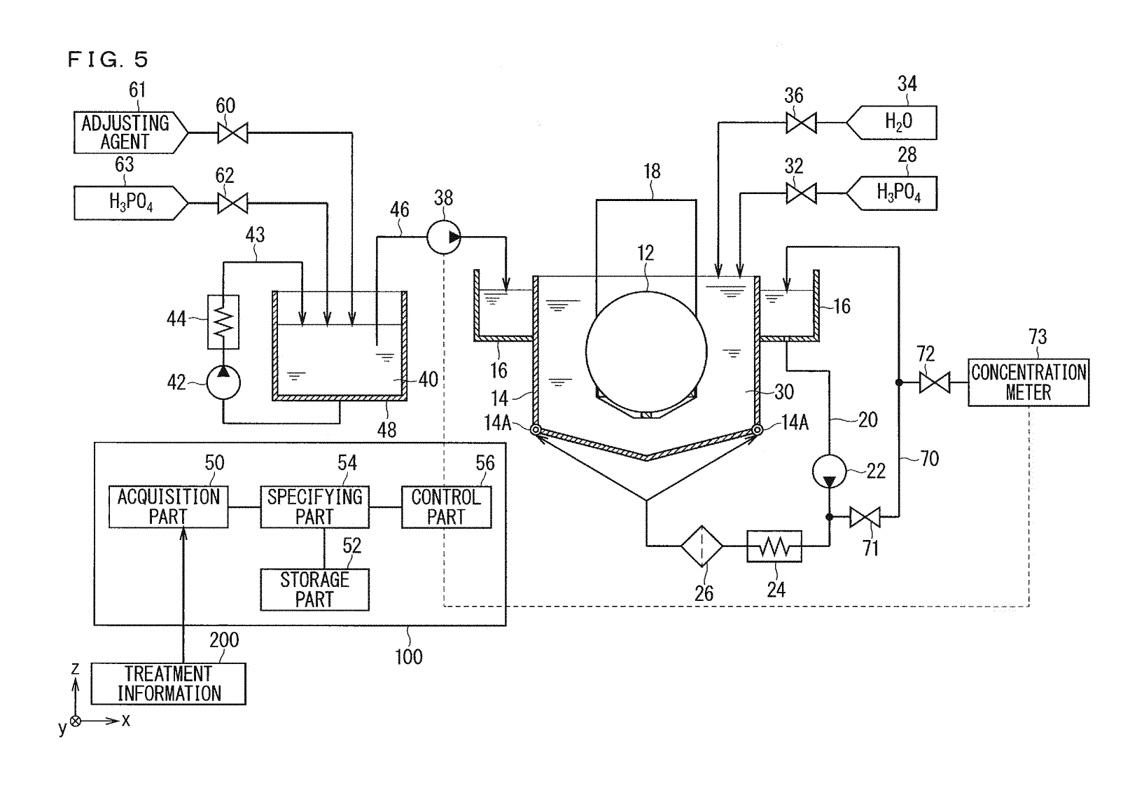

FIG. 5 is a view schematically exemplifying the constitutions of a substrate treatment apparatus according to the present preferred embodiment of a case with a concentration meter which measures the concentration of a change component in the treatment liquid 30.

As exemplified in FIG. 5, the substrate treatment apparatus is provided with a branch path 70 which branches from the circulation path 20 in addition to the constitutions exemplified in FIG. 1.

In the branch path 70, a valve 71 for flowing the treatment liquid 30 from the circulation path 20 into the branch path 70 and a valve 72 for flowing the treatment liquid 30 from the branch path 70 further into a concentration meter 73 are disposed.

The concentration meter 73 measures the concentration of the change component in the treatment liquid 30. For example, in a case in which the silicon concentration in the treatment liquid 30 is changed by etching treatment of the substrates 12, the concentration meter 73 corresponds to a silicon concentration meter.

When the concentration of the change component in the treatment liquid 30 is measured by the concentration meter 73, the measurement result is output to the control part 56. Then, in accordance with the measurement result, the control part 56 can adjust the replenishment control of the replenishment liquid 40 based on the predicted concentration change pattern. Specifically, when the concentration meter 73 shows a fact that the concentration of the change component in the treatment liquid 30 has changed, the control part 56 can adjust, for example, the replenishment amount of the replenishment liquid 40 or the concentration of the replenishment liquid 40 in accordance with the magnitude of the concentration change of the change component in the treatment liquid 30.

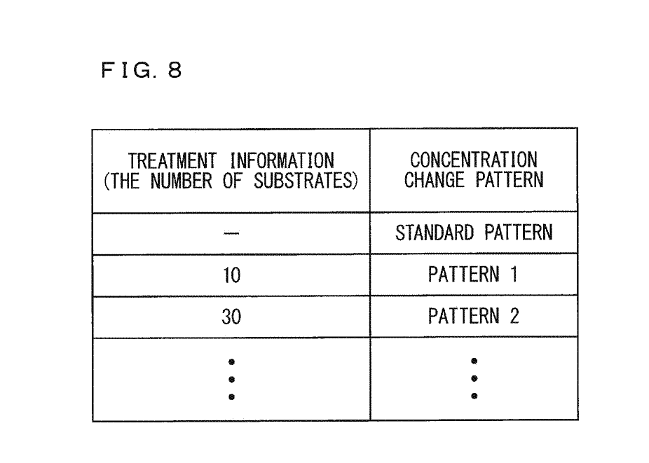

FIG. 8 shows an example of a correspondence table which is different from that described before by using FIG. 3. FIG. 8 shows a correspondence table of a case in which only the number of substrates is changed under standard substrate treatment conditions.

Items of the substrate treatment conditions include the information showing the species (for example, phosphoric acid aqueous solution, etc.) of the treatment liquid 30, the concentration of the phosphoric acid component, etc. contained in the treatment liquid 30, the temperature of the treatment liquid 30, and the liquid amount of the replenishment liquid 40. Even in the cases in which the substrate treatment is executed under the same standard substrate treatment conditions, if the number of the substrates immersed at the same time in the treatment tank 14 is different, the silicon concentration undergoes time lapse changes in different patterns.

The correspondence table of FIG. 8 stores a concentration change pattern (pattern 1) of a case in which the number of the substrates is 10, a concentration change pattern (pattern 2) of a case in which the number of the substrates is 30, and a standard concentration change pattern (standard pattern) of a case in which substrate treatment is carried out under the standard substrate treatment condition regardless of the number of the substrates. Note that the number of the substrates is not limited to these.

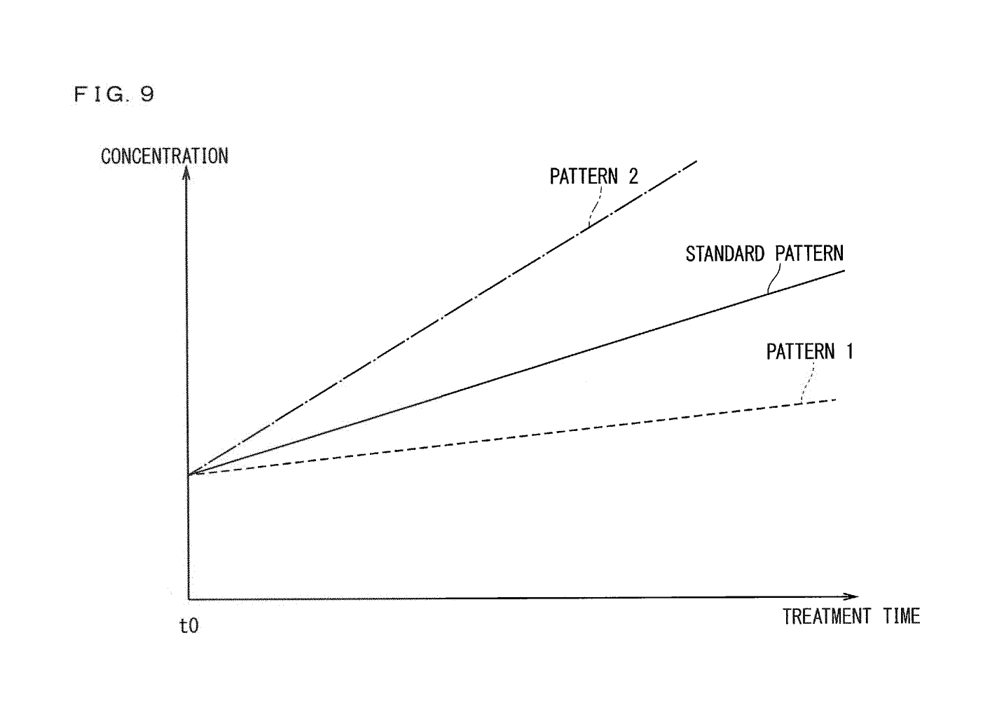

FIG. 9 shows the standard pattern, the concentration change pattern (pattern 2, dashed-dotted line) of the case in which the number of the substrates is 30, and the concentration change pattern (pattern 1, broken line) of the case in which the number of the substrates is 10. The pattern 2 has a higher change rate of the silicon concentration than that of the pattern 1. In this manner, the change rate of the silicon concentration is affected by the number of the substrates.

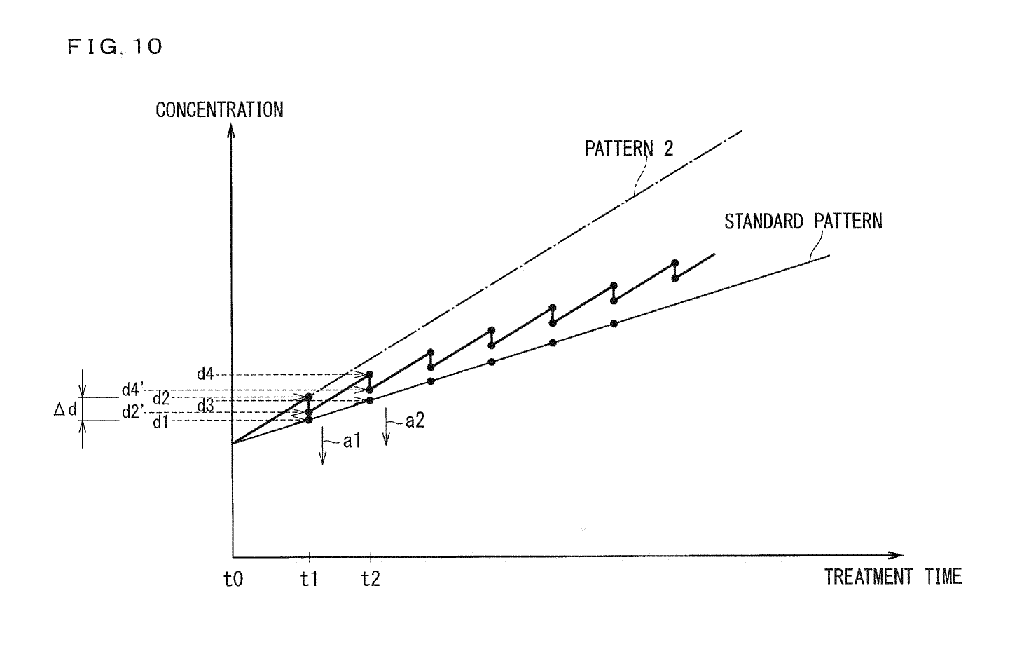

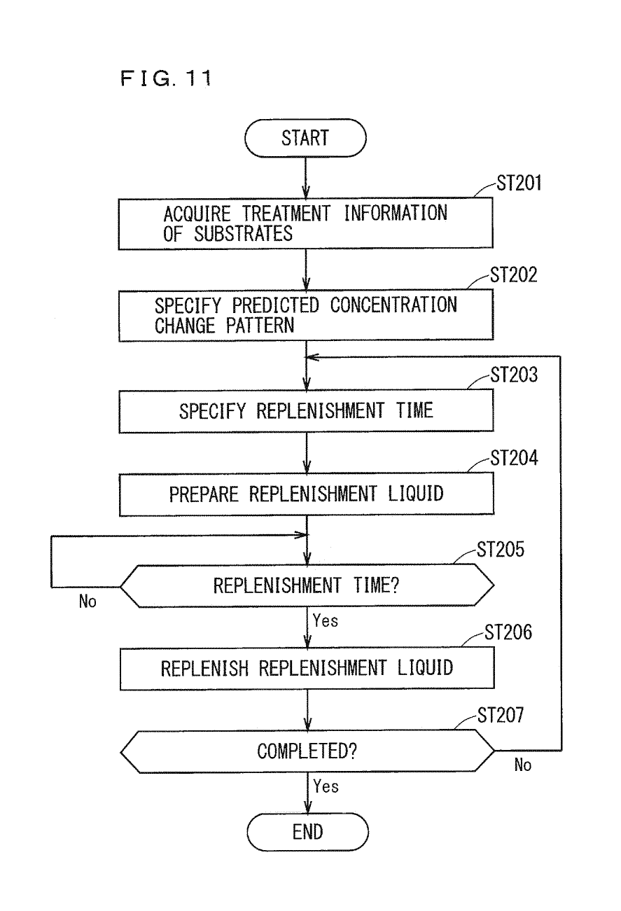

Next, control operation of the substrate treatment apparatus of the case in which the correspondence table shown in FIG. 8 is used will be described with reference to FIG. 9, FIG. 10, and FIG. 11. FIG. 10 is a graph showing time lapse changes of the silicon concentration of the treatment liquid 30 of the cases in which the concentration control of the treatment liquid 30 is carried out by the control part 56. In FIG. 10, a dashed-dotted line shows the pattern 2, a narrow solid line shows a standard pattern, and a bold solid line shows the transitions of the actual silicon concentration. FIG. 11 is a flow chart for describing a control flow.

First, the acquisition part 50 acquires the treatment information 200. More specifically, the acquisition part 50 acquires the number of the substrates 12 which are immersed at the same time in the treatment tank 14 (step ST201). In this case, it is assumed that 30 substrates 12 are to be immersed at the same time in the treatment tank 14. The specifying part 54 specifies the predicted concentration change pattern corresponding to the acquired treatment information of the substrates (step ST202). More specifically, the specifying part 54 specifies the concentration change pattern “pattern 2” corresponding to the number of the substrates, which is 30. Furthermore, the control part 56 specifies “standard pattern”.

By referencing the correspondence table, the control part 56 predicts that the silicon concentration in the treatment liquid 30 undergoes time lapse changes like the pattern 2. The control part 56 also predicts how the silicon concentration in the treatment liquid 30 deviates from the standard pattern along with lapse of time by comparing the pattern 2 with the standard pattern.

With reference to FIG. 10, the control part 56 stores a permissible deviation width of the silicon concentration with respect to the standard pattern, in other words, stores, as a permissible silicon concentration difference Δd, the permissible range showing how much the silicon concentration of the treatment liquid 30 can be permitted to deviate from the standard pattern. Then, the control part 56 predicts the time at which the treatment liquid 30 begins to have the permissible silicon concentration difference Δd. The control part 56 specifies the time at which the treatment liquid 30 is predicted to have the permissible silicon concentration difference Δd as replenishment time (step ST203). In the example of FIG. 10, it is assumed that the difference |d1-d2| between a silicon concentration d2 predicted based on the pattern 2 and a silicon concentration d1 predicted based on the standard pattern gets close to the permissible silicon concentration difference Δd at time t1. The control part 56 sets the time t1 as replenishment time t1. Then, when the treatment time reaches the replenishment time t1, the replenishment liquid 40 having a replenishment silicon concentration d2′, which is lower than a silicon concentration d2, is replenished to the treatment tank 14 through the outer tank 16, thereby preventing the silicon concentration of the treatment liquid 30 from exceeding the permissible silicon concentration difference Δd and deviating from the standard pattern.

Then, by the replenishment time t1, the control part 56 executes the control to complete preparation of the replenishment liquid 40 having the replenishment silicon concentration d2′ (step ST204). More specifically, the valve 60 and the valve 62 are opened to supply the adjusting agent and the phosphoric acid to the backup tank 48, and the open degrees of the valve 60 and the valve 62 are adjusted to store the replenishment liquid 40, which has the replenishment silicon concentration d2′, in the backup tank 48. Furthermore, the replenishment liquid 40 is circulated in the circulation path 43 while being heated by the heater 44, thereby increasing the temperature of the replenishment liquid 40 to a temperature equal to or higher than the liquid temperature of the treatment liquid 30.

The control part 56 judges whether the treatment time has reached the replenishment time t1 or not (step ST205) and, if the control part judges that the treatment time has reached the replenishment time t1 (Yes in step ST205), drives the pump 38 and replenishes the replenishment liquid 40 toward the outer tank 16 (step ST206). As a result, as shown by an arrow al in FIG. 10, the silicon concentration of the treatment liquid 30 drops to a silicon concentration d10 (d1<d10<d2). As a result, the difference between the actual silicon concentration of the treatment liquid 30 and the silicon concentration based on the standard pattern becomes less than the permissible silicon concentration difference Δd.

Then, the control part 56 judges whether the substrate treatment has been completed (step ST207). If it is judged that the treatment has not been completed, a transition to step ST203 is made, and next replenishment time t2 is specified. The control part 56 references, for example, the change rate of the pattern 2 after the replenishment time t1 to predict the transition of the silicon concentration of the treatment liquid 30 after the replenishment time t1. In the example of FIG. 10, it is assumed that the difference |d3-d4| between a silicon concentration d4 based on the pattern 2 and a silicon concentration d3 based on the standard pattern gets close to the permissible silicon concentration difference Δd at time t2. Therefore, the control part 56 specifies the time t2 as second replenishment time t2 (step ST203).

Thereafter, the control part 56 controls the valve 60, the valve 62, the pump 42, and the heater 44 so that the preparation of the replenishment liquid 40 having a replenishment silicon concentration d4′, which is less than the silicon concentration d4, is completed by the second replenishment time t2 (step ST204). If the control part 56 judges that the treatment time has reached the second replenishment time t2 (Yes in step ST205), the control part 56 controls the pump 38 to replenish the replenishment liquid 40 of the replenishment silicon concentration d4′ from the backup tank 48 toward the outer tank 16 (step ST206). As a result, as shown by an arrow a2 in FIG. 10, the silicon concentration of the treatment liquid 30 drops to a silicon concentration d30 (d3<d30<d4).

In this manner, the control part 56 predicts the transitions of the silicon concentration of the treatment liquid 30 in the substrate treatment based on the change pattern of the silicon concentration of the treatment liquid 30 associated with the number of the substrates which is one of the treatment information. Then, the time (replenishment time) at which the difference between the silicon concentration of the treatment liquid 30 and the silicon concentration based on the standard pattern can no longer be permitted is specified. By the treatment time reaches the replenishment time, the control part 56 completes the preparation of the replenishment liquid 40 having the silicon concentration which can reduce the difference between the silicon concentration of the treatment liquid 30 and the silicon concentration based on the standard pattern to within a permissible range.

As shown in FIG. 10, the required silicon concentration of the replenishment liquid 40 is different depending on the treatment time. More specifically, the silicon concentration d4′ required at the second replenishment time t2 is higher than the silicon concentration d2′ required at the first replenishment time t1. This is for a reason that, in a batch-type substrate treatment apparatus like that of the present preferred embodiment, the silicon concentration of the treatment liquid 30 usually increases along with elapse of the substrate treatment. Therefore, the replenishment liquid having the silicon concentration which is different depending on the treatment time has to be prepared in the backup tank 48. In the present preferred embodiment, since the future silicon concentration of the treatment liquid 30 can be predicted based on the silicon concentration change pattern, the preparation of the replenishment liquid 40 can be started before the replenishment time.

Note that the actual silicon concentration of the treatment liquid 30 deviates from the silicon concentration based on the pattern 2 every time the replenishment liquid 40 is replenished. Therefore, the prediction precision of the silicon concentration based on the pattern 2 is conceived to be lowered along with lapse of the treatment time. Therefore, the concentration meter 73 is disposed in the substrate treatment apparatus as shown in FIG. 5. The silicon concentration of the treatment liquid 30, which circulates in the branch path 70, is measured by the concentration meter 73, and the prediction result of the silicon concentration based on the pattern 2 may be complemented for by using the concentration value output from the concentration meter 73. Specifically, it is predicted that the replenishment liquid 40 having the replenishment concentration d4′ has to be replenished at the second replenishment time t2 based on the pattern 2. However, it is conceivable to use a method in which the timing to actually replenish the replenishment liquid 40 is determined based on the output of the concentration meter 73. By using such a method, the concentration of the treatment liquid 30 can be controlled with higher precision.

The correspondence table of the present preferred embodiment describes the single treatment information, which is the number of the substrates, and the concentration change patterns in a manner that they are mutually associated. However, it is also possible to use a correspondence table which describes a plurality of treatment informations and concentration change patterns in a manner that they are mutually associated.

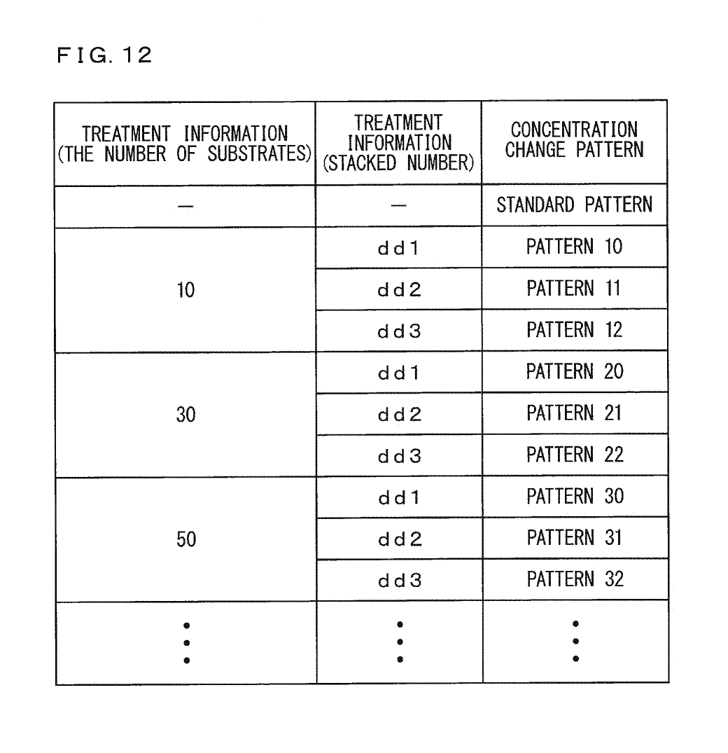

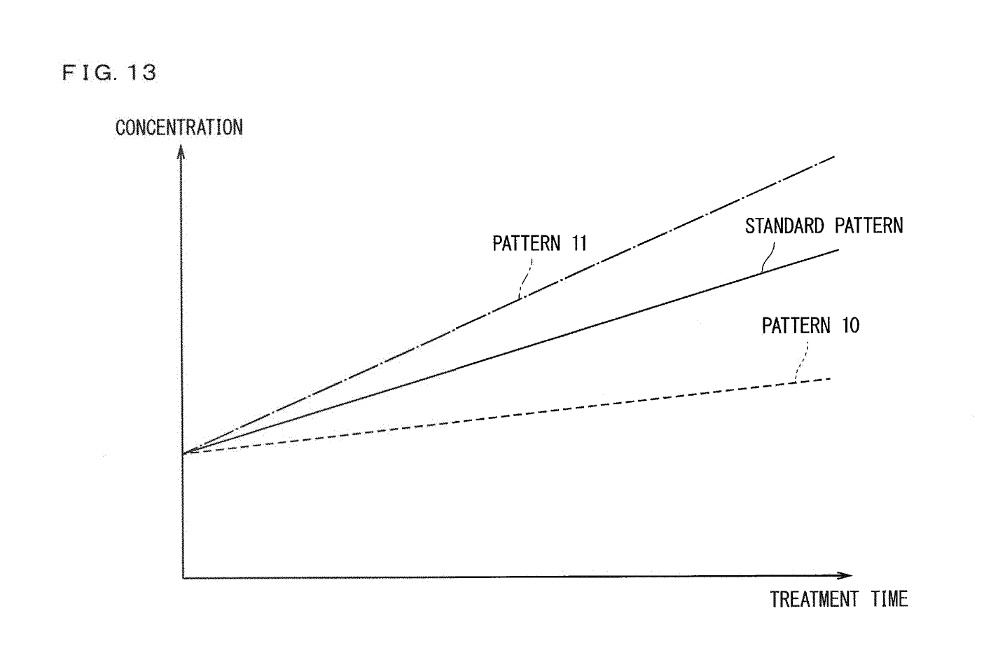

FIG. 12 shows a correspondence table which describes a plurality of treatment informations (the number of the substrates and the number of stacked patterns formed on the substrates 12) and concentration change patterns in a manner that they are mutually associated. For example, if the number of the substrates 12 (the number of substrates) to be immersed at the same time in the treatment tank 14 is 10 and the stacked number is dd1, the silicon concentration of the treatment liquid 30 is predicted to undergo transitions like a pattern 10 shown in FIG. 13. Similarly, if the number of the substrates is 10 and the stacked number is dd2 (dd1<dd2), the silicon concentration is predicted to undergo transitions like a pattern 11 shown in FIG. 13.

As described before, the larger the stacked number, the larger the amount of etching. Therefore, the amount of silicon which dissolves from the substrates 12 into the treatment liquid 30 during treatment becomes large. As a result, the increase rate of the silicon concentration during the treatment is conceivably higher in the pattern 11 than in the pattern 10.

In this manner, by using the correspondence table which describes a plurality of treatment informations associated with concentration change patterns, the transitions of the silicon concentration in the treatment liquid 30 can be predicted with higher precision.

<Effects Brought About by the Preferred Embodiment Described Above>

Next, the effects brought about by the preferred embodiment described above are exemplified. Note that, in the following description, the effects are described based on the specific constitutions exemplified in the preferred embodiment described above. However, within the range that brings about similar effects, the constitutions may be replaced by other specific constitutions exemplified in the present specification.

According to the preferred embodiment described above, the substrate treatment apparatus is provided with the treatment tank 14, the acquisition part 50, the storage part 52, the specifying part 54, and the control part 56. The treatment tank 14 is a container for treating the at least one substrate 12 with the treatment liquid 30. The acquisition part 50 acquires, in advance, the treatment information 200 of the substrates 12, which are to be treated in the treatment tank 14. The storage part 52 stores the correspondence table as correspondence information. The correspondence table is a table which describes the treatment information 200 and the plurality of concentration change patterns of the treatment liquid 30 respectively corresponding to the plurality of situations possible for the treatment information 200. The specifying part 54 references the correspondence table, thereby specifying, as a predicted concentration change pattern, a single concentration change pattern corresponding to the treatment information 200 of the substrates 12 acquired by the acquisition part 50. The control part 56 carries out the concentration control of the treatment liquid 30 based on the predicted concentration change pattern while the substrates 12 are treated in the treatment tank 14.

According to such constitutions, the concentration of the treatment liquid 30 can be controlled based on the specified predicted concentration change pattern while the substrates 12 are treated. Therefore, in a case in which the change of the component concentration in the treatment liquid 30 caused along the treatment of the substrates 12 is large and even in a case in which the time change of the component concentration is large, the concentration of the treatment liquid can be appropriately controlled while the substrates 12 are treated.

Note that the other constitutions exemplified in the specification of the present application other than these constitutions can be appropriately omitted. In other words, with at least these constitutions, the effects described above can be brought about.

However, even if at least one of the other constitutions exemplified in the specification of the present application is appropriately added to the constitutions described above, in other words, even if another constitution(s) exemplified in the specification of the present application not described as the constitutions described above is added to the constitutions described above, effects similar to those described above can be brought about.

Moreover, according to the preferred embodiment described above, the substrate treatment apparatus is provided with a replenishment part which replenishes the replenishment liquid 40 to the treatment tank 14 while the substrates 12 are treated in the treatment tank 14. The control part 56 controls the amount of the replenishment liquid 40 replenished by the replenishment part, thereby carrying out the concentration control of the treatment liquid 30. Herein, the replenishment part corresponds to, for example, the backup tank 48, which stores the replenishment liquid 40, and the pump 38, which flows the replenishment liquid 40 from the backup tank 48. According to such constitutions, by replenishing the replenishment liquid 40 while the substrates 12 are treated, the concentration of the treatment liquid 30 can be controlled while suppressing concentration changes of the change component in the treatment liquid 30 during the treatment of the substrates 12. Therefore, even if the change of the component concentration in the treatment liquid 30 caused along with the treatment of the substrates 12 is large, the concentration of the treatment liquid can be maintained while the substrates 12 are treated.

Moreover, according to the preferred embodiment described above, the substrates 12 are the substrates having stacked structures. According to such constitutions, even if the concentration of the treatment liquid 30 is largely changed along with the treatment of the stacked substrates which have a large amount of etching, the concentration of the treatment liquid can be maintained while the substrates 12 are treated.

Moreover, according to the preferred embodiment described above, the replenishment liquid 40 which has undergone temperature adjustment based on the temperature of the treatment liquid 30 is replenished to the treatment tank 14 by the replenishment part. According to such constitutions, as a result of adjusting the temperature of the replenishment liquid 40 in the backup tank 48 to a temperature close to the temperature of the treatment liquid 30 in the treatment tank 14, the temperature of the treatment liquid 30 in the treatment tank 14 is not easily changed even in a case in which the replenishment liquid 40 is replenished. Therefore, even in a case in which the replenishment liquid 40 is replenished, the treatment of the substrates 12 can be continued in the state in which the temperature of the treatment liquid 30 is appropriately maintained.

According to the preferred embodiment described above, in the substrate treatment method, the treatment information 200 of the substrates 12, which are to be treated in the treatment tank 14, is acquired in advance. Then, by referencing the correspondence table describing the treatment information 200 and the plurality of concentration change patterns of the treatment liquid 30 respectively corresponding to the plurality of situations possible for the treatment information 200, a single concentration change pattern corresponding to the acquired treatment information 200 of the substrates 12 is specified as a predicted concentration change pattern. Then, while the substrates 12 are treated in the treatment tank 14, the concentration control of the treatment liquid 30 is carried out based on the specified predicted concentration change pattern.

According to such constitutions, the concentration of the treatment liquid 30 can be controlled based on the specified predicted concentration change pattern while the substrates 12 are treated. Therefore, even if the change of the component concentration in the treatment liquid 30 caused along with the treatment of the substrates 12 is large, the concentration of the treatment liquid can be controlled while the substrates 12 are treated.

Note that the other constitutions exemplified in the specification of the present application other than these constitutions can be appropriately omitted. In other words, with at least these constitutions, the effects described above can be brought about.

However, even if at least one of the other constitutions exemplified in the specification of the present application is appropriately added to the constitutions described above, in other words, even if another constitution(s) exemplified in the specification of the present application not described as the constitutions described above is added to the constitutions described above, effects similar to those described above can be brought about.

If there is no particular limitation, the order of carrying out the treatment can be changed.

<About Modified Examples of Preferred Embodiment Described Above>

In the preferred embodiment described above, the quality of materials, materials, dimensions, shapes, relative disposition relations, conditions of implementation, etc. of the constituent elements are described in some cases. However, these are examples in all aspects, and they are not limited to those described in the specification of the present application.

Therefore, numerous modified examples and equivalents which are not shown as examples assumed to be in the scope of the techniques disclosed in the specification of the present application. For example, a case in which at least one constituent element is modified, a case in which it is added, and a case in which it is omitted are included.

Note that the present invention can modify or omit arbitrary constituent elements of the present preferred embodiment within the range of the invention.

While the invention has been shown and described in detail, the foregoing description is in all aspects illustrative and not restrictive. It is therefore understood that numerous modifications and variations can be devised without departing from the scope of the invention.

What is claimed is:

1. A substrate treatment method of treating at least one substrate in a treatment tank with treatment liquid, the substrate treatment method including the following processes of:
acquiring in advance treatment information of said substrate to be treated in said treatment tank;
specifying a predicted concentration change pattern corresponding to said acquired treatment information of said substrate by referencing correspondence information describing a plurality of situations possible for said treatment information and a plurality of concentration change patterns of said treatment liquid prepared in advance to respectively correspond to said plurality of situations of said treatment information; and
carrying out concentration control of said treatment liquid based on said predicted concentration change pattern while said substrate is treated in said treatment tank.

2. The substrate treatment method according to claim 1, further comprising the process of
replenishing replenishment liquid to said treatment tank while said substrate is treated in said treatment tank, wherein
concentration control of said treatment liquid is carried out by controlling the amount of said replenishment liquid replenished based on said predicted concentration change pattern.

3. The substrate treatment method according to claim 1, wherein
said plurality of situations of said treatment information of said substrate include information about a situation of the number of said substrate(s) to be treated in said treatment tank.

4. The substrate treatment method according to claim 1, wherein
said plurality of situations of said treatment information of said substrate include information about a situation of time to treat said substrate in said treatment tank.

5. The substrate treatment method according to claim 1, wherein
said plurality of situations of said treatment information of said substrate include information about a situation of speed to treat said substrate in said treatment tank.

6. The substrate treatment method according to claim 1, wherein
said plurality of situations of said treatment information of said substrate include information about a situation of a surface area of a surface pattern formed on said substrate to be treated in said treatment tank.

7. The substrate treatment method according to claim 1, wherein
said substrate is a substrate having a stacked structure.

8. The substrate treatment method according to claim 2, wherein
said replenishment liquid replenished to said treatment tank has undergone temperature adjustment based on a temperature of said treatment liquid.

9. A substrate treatment apparatus comprising:
a treatment tank that stores treatment liquid and immerses at least one substrate in said stored treatment liquid to carry out substrate treatment of said substrate;
a backup tank that is provided separately from said treatment tank, the backup tank replenishing replenishment liquid prepared to a predetermined concentration toward said treatment tank;
liquid sending means that sends said replenishment liquid from said backup tank toward said treatment tank;
an acquisition part that acquires in advance treatment information about said substrate to be immersed in said treatment tank;
a storage part that stores correspondence information describing a plurality of situations possible for said treatment information and describing a plurality of concentration change patterns prepared in advance to respectively correspond to said plurality of situations of said treatment information;
a specifying part that specifies a predicted concentration change pattern corresponding to said treatment information of said substrate acquired by said acquisition part by referencing said correspondence information; and
control means that executes
concentration prediction control of predicting a future concentration of said treatment liquid based on said specified predicted concentration change pattern,
replenishment liquid concentration specifying control of specifying the concentration of replenishment liquid capable of changing said future concentration,
preparation control of preparing said replenishment liquid in advance in said backup tank before replenishing said replenishment liquid from said backup tank toward said treatment tank, and
liquid sending control of controlling said liquid sending means so as to send said prepared replenishment liquid from said backup tank toward said treatment tank during said substrate treatment.

10. The substrate treatment apparatus according to claim 9, wherein
said storage part further stores a standard concentration change pattern showing a standard concentration transition of said treatment liquid in a case in which substrate treatment is executed under a predetermined substrate treatment condition in said treatment tank, and
said control means executes said replenishment liquid concentration specifying control based on the concentration change pattern of said substrate immersed in said treatment tank and said standard concentration change pattern.

11. A substrate treatment method of a substrate treatment apparatus having: a treatment tank that stores treatment liquid and immerses at least one substrate in said stored treatment liquid to carry out substrate treatment of said substrate; a backup tank that is separately provided from said treatment tank, the backup tank replenishing replenishment liquid prepared to a predetermined concentration toward said treatment tank; liquid sending means that sends said replenishment liquid from said backup tank toward said treatment tank; and a storage part that in advance stores correspondence information describing a plurality of situations possible for treatment information about said substrate to be immersed in said treatment tank and describing a plurality of concentration change patterns of said treatment liquid prepared in advance to respectively correspond to the plurality of situations of said treatment information, the substrate treatment method including the following processes of:
acquiring in advance treatment information about said substrate to be immersed in said treatment tank;
specifying a predicted concentration change pattern corresponding to said acquired treatment information of said substrate by referencing said correspondence information;
predicting a future concentration of said treatment liquid based on said specified predicted concentration change pattern;
specifying the concentration of said replenishment liquid capable of changing said future concentration;
preparing said replenishment liquid in said backup tank in advance before replenishing said replenishment liquid from said backup tank toward said treatment tank; and
sending said prepared replenishment liquid from said backup tank toward said treatment tank during said substrate treatment.
